(19) United States
(12) Patent Application Publication
(10) Pub. No.: US 2016/0064614 A1
(43) Pub. Date: Mar. 3, 2016

(54) LIGHT EMITTING DIODE PACKAGE AND MANUFACTURING METHOD THEREOF

(71) Applicant: ADVANCED OPTOELECTRONIC TECHNOLOGY, INC., Hsinchu Hsien (TW)

(72) Inventors: CHIEN-SHIANG HUANG, Hukou (TW); TZU-CHIEN HUNG, Hukou (TW)

(21) Appl. No.: 14/826,397

(22) Filed: Aug. 14, 2015

(30) Foreign Application Priority Data
Sep. 2, 2014 (CN) 201410442080.6

(51) Int. Cl. H01L 33/44

(52) U.S. Cl. CPC H01L 33/44; H01L 2933/0025; H01L 2933/0033

(57) ABSTRACT

A light emitting diode package includes a substrate, a light emitting diode mounted on the substrate by flip chip bonding and a protective layer. The light emitting diode includes an epitaxial layer, a first electrode and a second electrode on the epitaxial layer. The first electrode and the second electrode are spaced apart from each other. The first and second electrodes are embedded in the protective layer. This disclosure also relates to a method for manufacturing the light emitting diode package.

### FIELD

The subject matter relates to a semiconductor luminous element, and particularly relates to a light emitting diode package and manufacturing method thereof.

### BACKGROUND

A traditional light emitting diode includes a substrate, electrode structures fixed on the substrate and a light emitting diode mounted on the substrate and electrically connected to the electrode structures. The light emitting diode includes an epitaxial structure, a first electrode and a second electrode. The first electrode and the second electrode of the light emitting diode are electrically connected to the electrode structures. However, the first electrode and the second electrode are exposed to the outside and may be exposed to the moisture, thereby damaging the light emitting diode.

### BRIEF DESCRIPTION OF THE DRAWINGS

Implementations of the present technology will now be described, by way of example only, with reference to the attached figures:

FIG. 1 is an assembly schematic view of a light emitting diode package in accordance with a first exemplary embodiment of the present disclosure.

FIG. 2 is an assembly schematic view of a light emitting diode package in accordance with a second exemplary embodiment of the present disclosure.

FIG. 3 is an assembly schematic view of a light emitting diode package in accordance with a third exemplary embodiment of the present disclosure.

FIG. 4 is an assembly schematic view of a light emitting diode package in accordance with a fourth exemplary embodiment of the present disclosure.

FIG. 5 is an assembly schematic view of a light emitting diode package in accordance with a fifth exemplary embodiment of the present disclosure.

FIGS. 6-15 are cross-sectional views showing semi-finished light emitting diodes package processed by different steps of a method for manufacturing a light emitting diode package in accordance with an exemplary embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures and components have not been described in detail so as not to obscure the related relevant feature being described. Also, the description is not to be considered as limiting the scope of the exemplary embodiments described herein. The drawings are not necessarily to scale and the proportions of certain parts have been exaggerated to better illustrate details and features of the present disclosure.

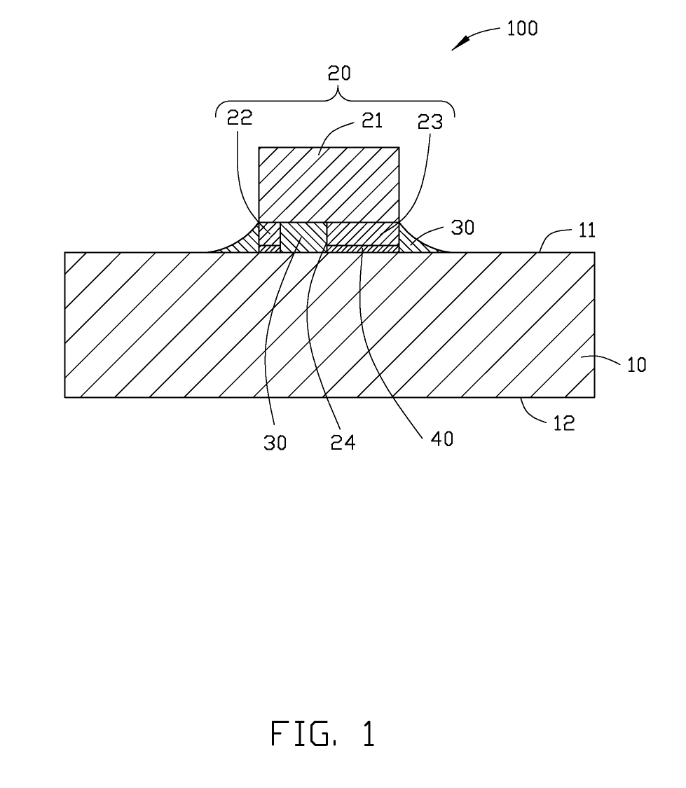

FIG. 1 shows a light emitting diode package 100 of a first exemplary embodiment in the present disclosure.

In the first exemplary embodiment, the light emitting diode package 100 includes a substrate 10 and a light emitting diode 20 mounted on the substrate 10 by flip chip bonding. The light emitting diode 20 includes an epitaxial substrate 21, a first electrode 22 and a second electrode 23. The epitaxial structure 21 includes a bottom surface 211 and side surfaces 212. The side surfaces 212 extend upwardly from the bottom surface 211. The first electrode 22 and the second electrode 23 are spaced apart from each other and fixed on the bottom surface 211 of the epitaxial structure 21. The first electrode 22 and the second electrode 23 are embedded in a protective layer 30.

The substrate 10 is a package board with good thermal convection. The substrate 10 includes a first surface 11 and a second surface 12 opposite to the first surface 11. Electrode structures (not shown in FIGs) are configured on the first surface 11 of the substrate 10 to electrically connect to the light emitting diode 20. The substrate 10 can be made of materials having a high thermal conductivity, such as Ni, Cu, Au, Ag, or Al and so on. The substrate 10 can be a printed circuit board with a metallic base. Preferably, a thickness of the substrate 10 is less than 50 μm.

The first electrode 22 and the second electrode 23 of the light emitting diode 20 can be directly welded to the electrode structures of the substrate 10. In this exemplary embodiment, the light emitting diode 20 is mounted on the first surface 11 of the substrate 10 through an electronic film 40. The electronic film 40, the first electrode 22 and the second electrode 23 are embedded in the protective layer 30. The first electrode 22 and the second electrode 23 can be made of Ni, Ag, Pt, Au, Ti or Cr. A gap 24 is defined between the first electrode 22 and the second electrode 23. The gap 24 can also be filled with the protective layer 30.

The protective layer 30 is made of insulating materials. Preferably, the protective layer 30 is spin on glass (SOG). The SOG can be made of Siloxane, SiO2, fluorin, carbon-doped and Silicate.

The protective layer 30 extends upwardly from the first surface 11 of the substrate 10 along a direction from the substrate 10 toward the light emitting diode 20, thereby covering the first electrode 22 and the second electrode 23. In this exemplary embodiment, the protective layer 30 extends upwardly until the first electrode 22 and the second electrode 23 are embedded therein and the protective layer 30 contacts the bottom surface 211 of the epitaxial structure 21.

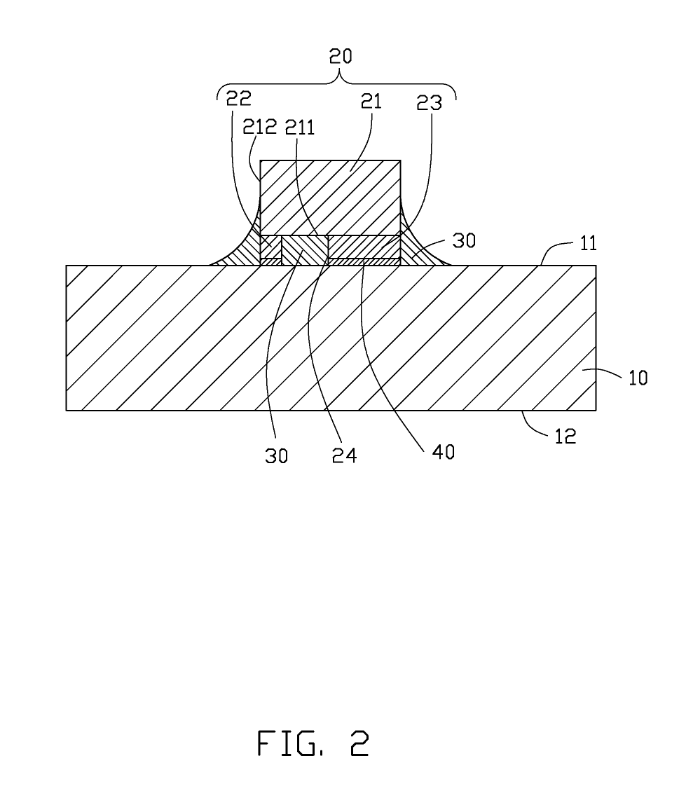

FIG. 2 shows a light emitting diode package of a second exemplary embodiment in the present disclosure. In the second exemplary embodiment, the protective layer 30 extends upwardly until the first electrode 22 and the second electrode 23 are embedded therein and the protective layer 30 covers part of the side surfaces 212 of the epitaxial structure 21.

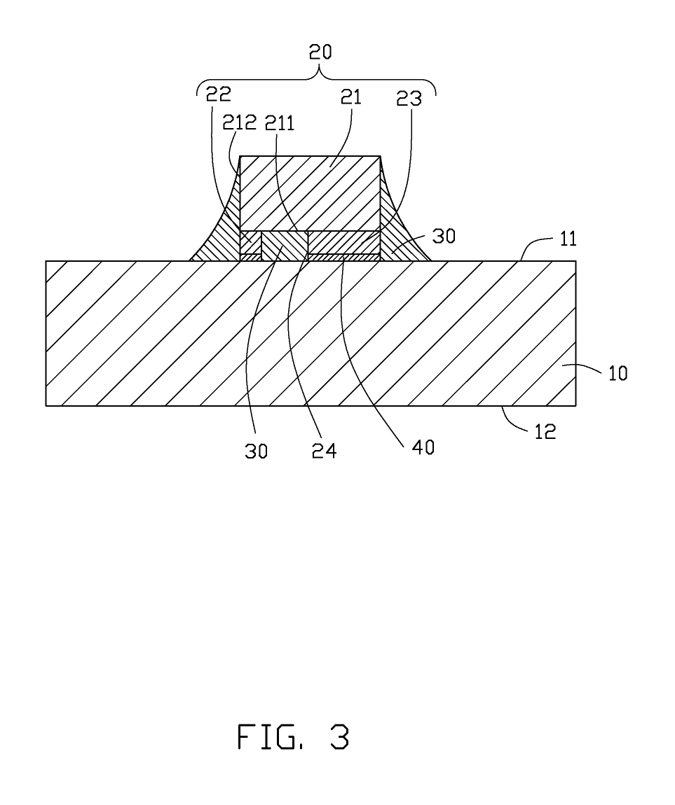

FIG. 3 shows a light emitting diode package of a third exemplary embodiment in the present disclosure. In the third exemplary embodiment, the protective layer 30 extends upwardly until the first electrode 22 and the second electrode 23 are embedded therein and the protective layer 30 covers whole of the side surfaces 212 of the epitaxial structure 21.

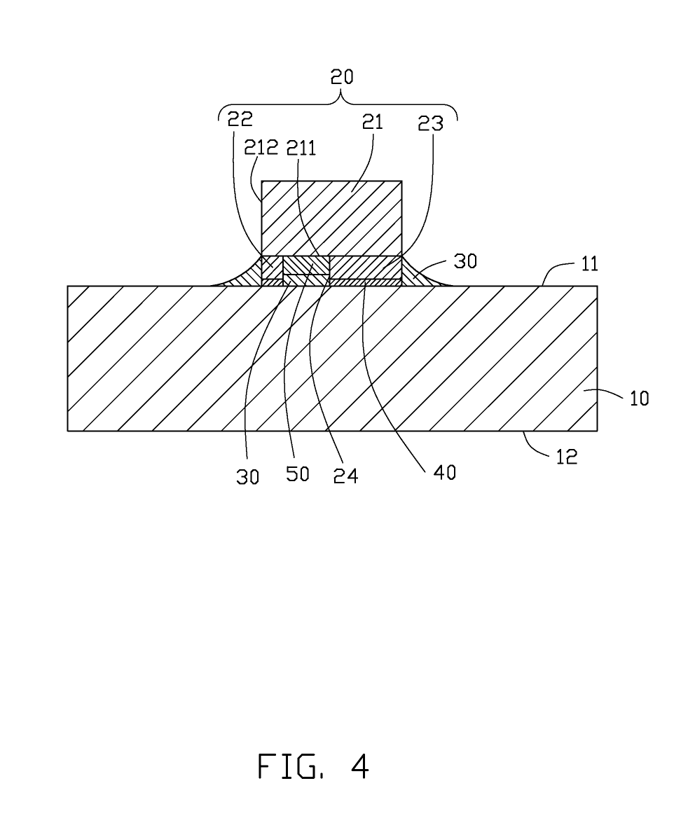

FIG. 4 shows a light emitting diode package of a fourth exemplary embodiment in the present disclosure.

Referring to FIG. 4, the gap 24 between the first electrode 22 and the second electrode 23 is filled with the protective layer 30 and an insulating layer 50. The protective layer 30 and the insulating layer 50 are stacked. The protective layer 30 is formed on the first surface 11 of the substrate 10. The insulating layer 50 is sandwiched between the protective layer 30 and the epitaxial structure 21.

The insulating layer 50 is made of SiO₂, Si₃N₄, Al₂O₃, AN and HC hydrocarbons. Heat generated from the epitaxial structure 21 is transferred from the insulating layer 50 to the substrate 10 more quickly when a thickness of the insulated 50 is less than 20 μm.

In this exemplary embodiment, because the first electrode 22 and the second electrode 23 of the light emitting diode 20 are embedded in the protective layer 30, the first electrode 22 and the second electrode 23 can be protected from moisture, thereby increasing reliability and stability of the light emitting diode package.

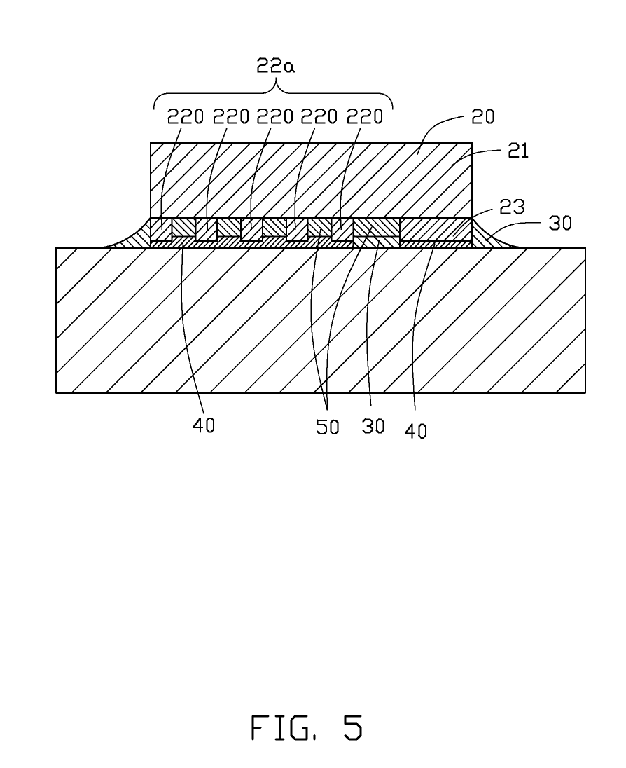

FIG. 5 shows a light emitting diode package of a fifth exemplary embodiment in the present disclosure.

Referring to FIG. 5, the first electrode 22a includes a plurality of spaced apart electronic pins 220. The electronic pins 220 are embedded in the protective layer 30.

The insulating layers 50 are filled between every two adjacent electronic pins 220. Electrical connection strength between first electrodes 22a and the substrate 10 is enhanced. Even if there is a pin 220 disconnected, normal operation of the light emitting diode 20 will not be affected. Additionally, heat generated from the epitaxial structure 21 can be transferred from the plurality of electronic pins 220 to the substrate 10, while heat dissipating efficiency of the light emitting diode package 100 is improved.

A method for manufacturing a light emitting diode package is also provided in the present disclosure.

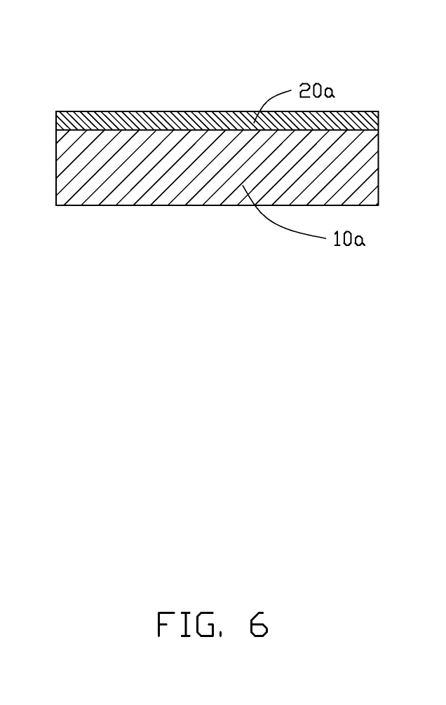

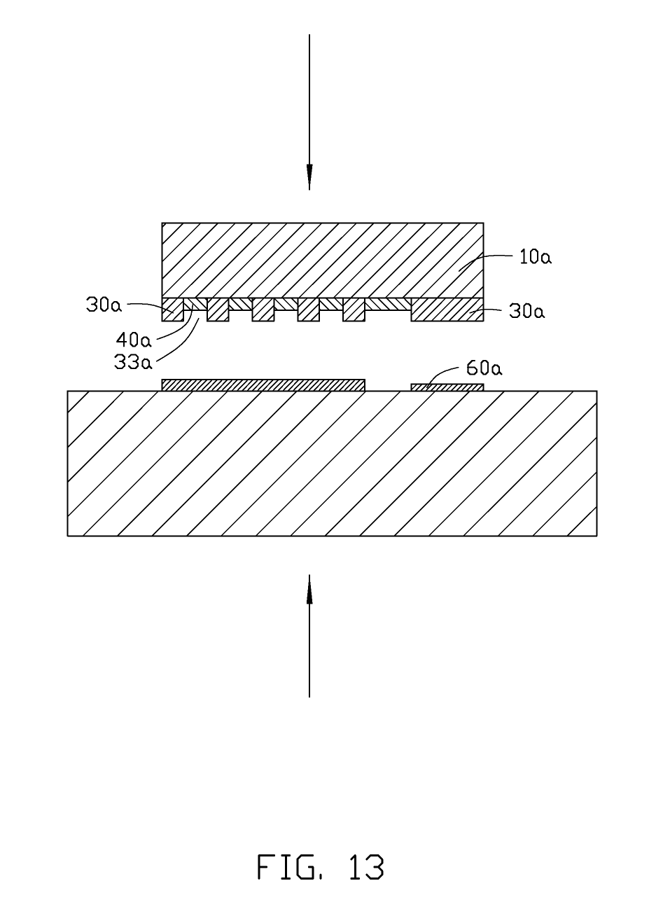

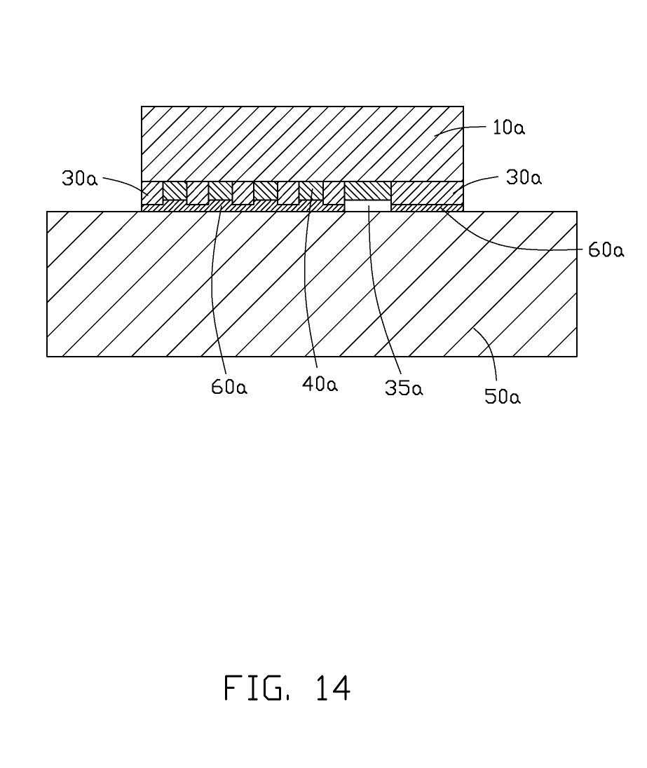

Referring from FIGS. 6-15, the method for manufacturing the light emitting diode package includes:
forming a photoresist layer 20a on a surface of an epitaxial structure 10a;
defining a plurality of first slots 21a on the photoresist layer 20a;
forming a plurality of metal layers 30a in the first slots 21a;
removing the residual photoresist layer 20a, therewith a plurality of second slots 31a formed between the metal layers 30a;
forming a plurality of insulating layers 40a in the second slots 31a to form a light emitting diode 100a; and the metal layers 30a being classified as first electrodes and a second electrode;
mounting the light emitting diode 100a on a substrate 50a; and
forming a protective layer 70a made of insulating materials on the substrate 50a with the metal layers 30a embedded in the protective layer 70.

Referring to FIG. 6, the photoresist layer 20a can cover the whole surface of the epitaxial structure 10a. The epitaxial structure 10a includes an N-type semiconductor layer, an active layer and a P-type semiconductor layer.

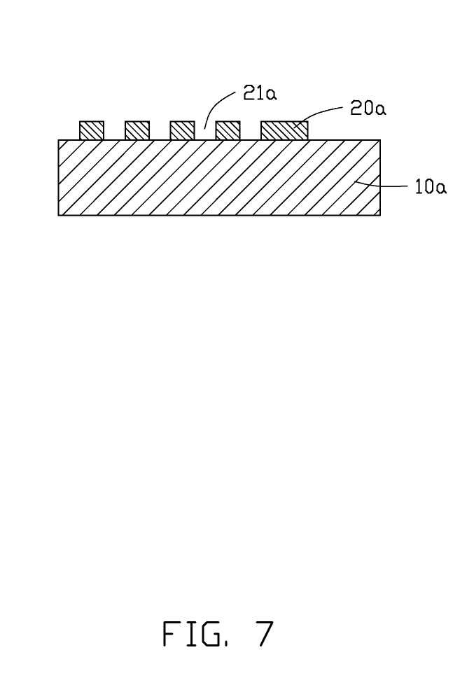

Referring to FIG. 7, the first slots 21a are spaced apart from and parallel to each other. In this exemplary embodiment, a number of the first slots 21a is six. The first slots 21a can be made via a yellow microlithography process.

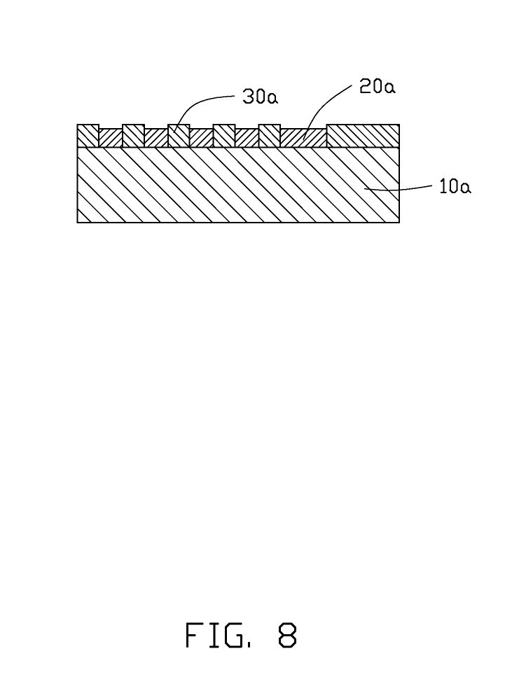

Referring to FIG. 8, each metal layer 30a is filled in a corresponding first slot 21a. The metal layer 30a can be made of nickel, silver, platinum, chrome, gold or complex metal. The metal layer 30a is formed in the corresponding first slot 21a by evaporation.

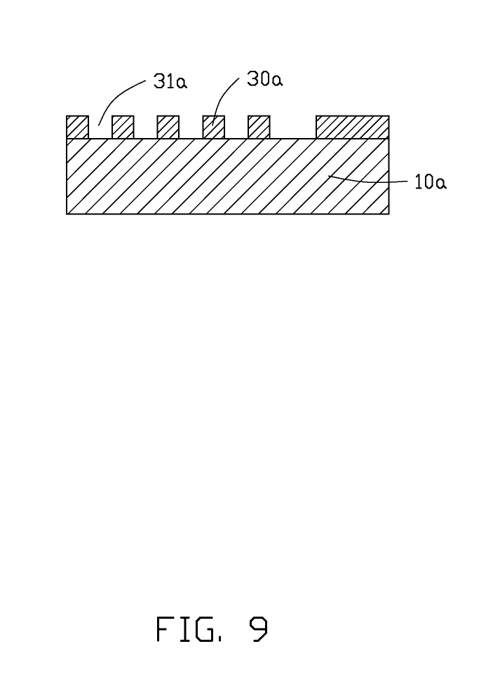

Referring to FIG. 9, each second slot 31a is defined between two adjacent metal layers 30a.

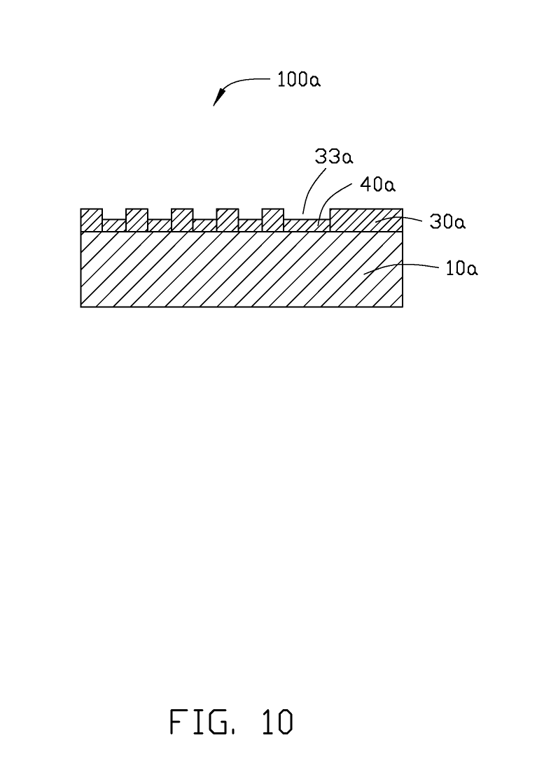

Referring to FIG. 10, a plurality of insulating layers 40a are configured in the second slots 31a to form a light emitting diode 100a. A thickness of each insulating layer 40a is less than a depth of a corresponding second slot 31a, therewith a third slot 33a defined between top of the insulating layer 40a and side surfaces of the second slot 31a. In this exemplary embodiment, the metal layer 30a located on right of the epitaxial structure 10a is functioned as a second electrode and the other metal layers 30a are functioned as first electrodes.

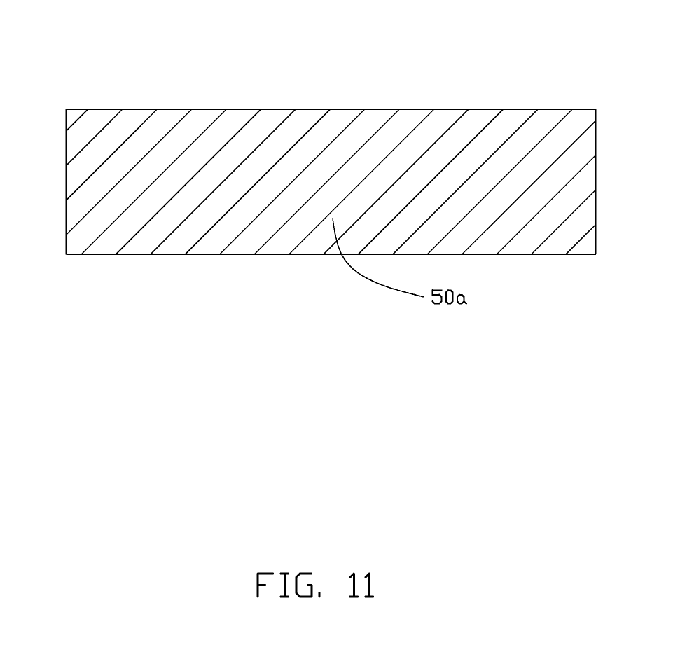

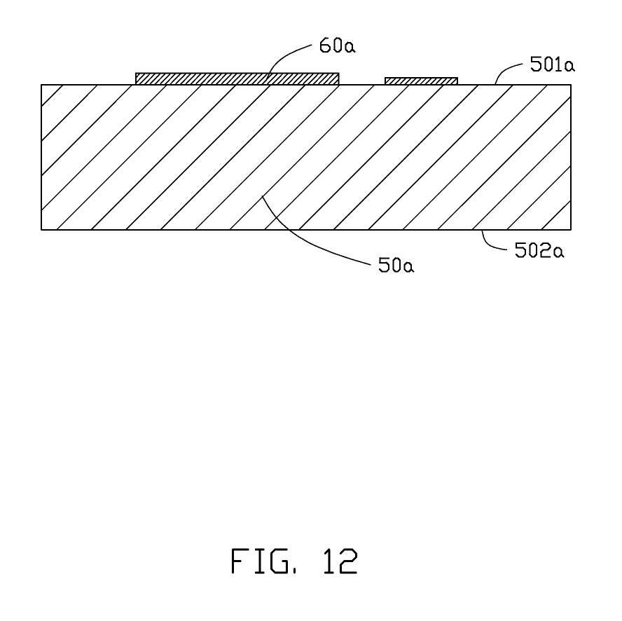

Referring to FIG. 11 and FIG. 12, the substrate 50a has good thermal convection and it can be a metallic printed circuit board. The substrate 50a includes a first surface 501a and a second surface 502a opposite to the first surface 501a. Electrode structures (not shown in FIGs) are configured on the first surface 501a of the substrate 50a to electrically connect to the light emitting diode 100a.

Referring to FIG. 12 to FIG. 14, fixing the light emitting diode 100a on the substrate 50a includes:

An electronic film 60a is formed on the first surface 501a of the substrate 50a. The light emitting diode 100a is pressed onto the substrate 50a with the electronic film 60a positive to the metal layers 30a of the light emitting diode 100a and the electronic film 60a filling the third slots 33a. In this exemplary embodiment, a spaced apart part 35a is defined between the substrate 50a and the insulating layer 40a located between the first electrode and the second electrode.

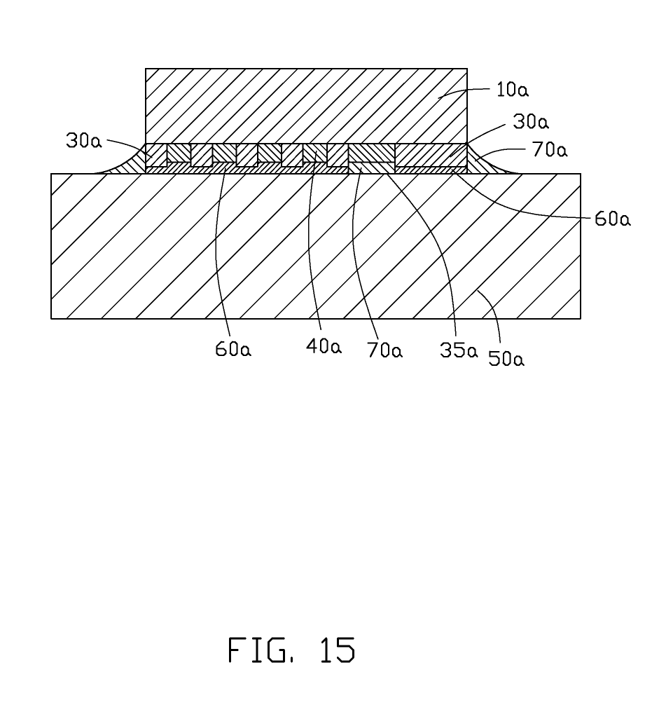

Referring to FIG. 15, a protective layer 70a is formed on the first surface 501a of the substrate 50a. The metal layers 30a are embedded by the protective layer 70a. The spaced apart part 35a between the first electrode and the second electrode can also be filled by the protective layer 70a. Preferably, the protective layer 70a is spin on glass (SOG).

The exemplary embodiment shown and described above is only an example. Many details are often found in the art such as the other features of the protective layer. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the exemplary embodiments described above may be modified within the scope of the claims.

What is claimed is:

1. A light emitting diode package, comprising:
a substrate;
a light emitting diode mounted on the substrate by flip chip bonding,
the light emitting diode comprising an epitaxial structure, a first electrode and a second electrode,
the first electrode and the second electrode being fixed on the epitaxial structure and spaced apart from each other; and
a protective layer formed on the substrate and being embedded the first electrode and the second electrode, and the protective layer being made of insulated materials.

2. The light emitting diode package of claim 1, wherein the epitaxial structure comprises a bottom surface and side surfaces extending from the bottom surface upwardly, the first electrode and the second electrode are formed on the bottom surface.

3. The light emitting diode package of claim 2, wherein the protective layer extends upwardly until the first electrode and the second electrode are embedded in the protective layer and the protective layer contacts a bottom surface of the epitaxial structure.

4. The light emitting diode package of claim 2, wherein the protective layer extends upwardly until the first electrode and the second electrode are embedded in the protective layer and the protective layer covers part of side surfaces of the epitaxial structure.

5. The light emitting diode package of claim 2, wherein the protective layer extends upwardly until the first electrode and the second electrode are embedded in the protective layer and the protective layer covers whole of side surfaces of the epitaxial structure.

6. The light emitting diode package of claim 1, wherein a gap is defined between the first electrode and the second electrode, and the gap is filled with the protective layer.

7. The light emitting diode package of claim 1, wherein a gap is defined between the first electrode and the second electrode, the gap is filled with the protective layer and an insulating layer, and the protective layer and the insulating layer are stacked.

8. The light emitting diode package of claim 7, wherein the protective layer is formed on a surface of the substrate and the insulating layer is sandwiched between the protective layer and the epitaxial structure.

9. The light emitting diode package of claim 8, wherein the protective layer is made of Siloxane, SiO2, fluorin, carbon-doped and Silicate.

10. The light emitting diode package of claim 9, wherein the insulating layer is made of SiO₂, Si₃N₄, Al₂O₃, AN and HC hydrocarbons.

11. A method for manufacturing a light emitting diode package comprising:
forming a photoresist layer on a side of an epitaxial structure;
defining a plurality of first slots on the photoresist layer;
forming a plurality of metal layers in the first slots;
removing the residual photoresist layer, therewith a plurality of second slots formed between the metal layers;
forming a plurality of insulating layers in the second slots to form a light emitting diode; and the metal layers being classified as first electrodes and a second electrode;
mounting the light emitting diode on a substrate; and
forming a protective layer on the substrate with the metal layers embedded, the protective layer being made of insulating materials.

12. The method for manufacturing a light emitting diode package of claim 11, wherein in the process of forming the photoresist layer, the photoresist layer covers the whole side of the epitaxial structure.

13. The method for manufacturing a light emitting diode package of claim 11, wherein the first slots are spaced apart from and parallel to each other.

14. The method for manufacturing a light emitting diode package of claim 11, wherein in the process of forming the metal layers, each metal layer is filled in a corresponding first slot.

15. The method for manufacturing a light emitting diode package of claim 14, wherein the metal layer is made of nickel, silver, platinum, chrome, gold or complex metal.

16. The method for manufacturing a light emitting diode package of claim 11, wherein in the process of forming the insulating layers, a thickness of each insulating layer is less than a depth of a corresponding second slot, therewith a third slot defined between top of the insulating layer and side surfaces of the second slot.

17. The method for manufacturing a light emitting diode package of claim 16, wherein the third slot is filled with the protective layer.

18. The method for manufacturing a light emitting diode package of claim 10, wherein the substrate comprises a first surface and a second surface opposite to the first surface.

19. The method for manufacturing a light emitting diode package of claim 18, wherein the process of fixing the light emitting diode on the substrate further comprises:
an electronic film being formed on the first surface of the substrate;
the light emitting diode being pressed onto the substrate with the electronic film positive to the metal layers.

20. The method for manufacturing a light emitting diode package of claim 10, wherein the protective layer is spin on glass.
